(19) United States
(12) Patent Application Publication
(10) Pub. No.: US 2015/0372223 A1
(43) Pub. Date: Dec. 24, 2015

(54) Strap Configuration to Reduce Mechanical Stress Applied to Stress Sensitive Devices

(71) Applicant: Crocus Technology Inc., Santa Clara, CA (US)

(72) Inventors: Bertrand Cambou, Palo Alto, CA (US); Ken Mackay, Le Sappey en Chartreuse (FR); Ruby Yehoshua, Sunnyvale, CA (US)

(73) Assignee: Crocus Technology Inc., Santa Clara, CA (US)

(21) Appl. No.: 14/734,960

(22) Filed: Jun. 9, 2015

Related U.S. Application Data
(60) Provisional application No. 62/013,697, filed on Jun. 18, 2014.

(51) Int. Cl. H01L 43/02; H01L 43/08

(52) U.S. Cl. CPC H01L 43/02; H01L 43/08

(57) ABSTRACT

An apparatus includes an elongated strap with a first platform and a second platform linked by a connector that is substantially narrower than the first platform and the second platform, where the first platform and the second platform are each configured to receive a stress sensitive device.

### CROSS REFERENCE TO RELATED APPLICATIONS

This application claims priority to U.S. Provisional Patent Application Ser. No. 62/013,697, filed Jun. 18, 2014, the contents of which are incorporated herein by reference.

### FIELD OF THE INVENTION

This invention relates generally to fabricating electronic devices. More particularly, this invention relates to a strap configuration to reduce mechanical stress applied to stress sensitive devices.

### BACKGROUND OF THE INVENTION

Stress sensitive devices, such as circular Magnetic Tunnel Junctions (MTJs), are very sensitive to external mechanical stress. Such devices are particularly sensitive to anisotropic mechanical stress. These mechanical stresses couple through the magnetostriction of the materials to disturb the magnetic properties of the MTJ based devices. The local interconnects placed just underneath the magnetic stack of the circular MTJ can create unwelcomed mechanical stress. Conductive layers placed underneath the MTJ, which are referred to as a “strap”, have a rectangular shape to connect the active junction to a second junction, or to a via that is connected to a different conductive layer. The straps are commonly manufactured with highly compressive materials, such as Tantalum or Tantalum nitride. The rectangular shape is by design anisotropic; this creates a large anisotropic compressive stress along the long axis. As a result of magnetostriction coupling effects, the stress creates anisotropy of the magnetic properties of the MTJ perpendicular to the long axis of the rectangular strap. It would be desirable to have a strap structure that reduces such stress.

### SUMMARY OF THE INVENTION

An apparatus includes an elongated strap with a first platform and a second platform linked by a connector that is substantially narrower than the first platform and the second platform, where the first platform and the second platform are each configured to receive a stress sensitive device.

### BRIEF DESCRIPTION OF THE FIGURES

The invention is more fully appreciated in connection with the following detailed description taken in conjunction with the accompanying drawings, in which:

FIG. 1 is a perspective view of a stress sensitive device mounted on a prior art strap.

FIG. 2 is a top view of a stress sensitive device mounted on a prior art strap.

FIG. 3 illustrates stress forces versus strap length for prior art straps.

FIG. 4 is a perspective view of a strap configured in accordance with an embodiment of the invention.

FIG. 5 illustrates stress forces versus strap length for a strap configured in accordance with an embodiment of the invention.

Like reference numerals refer to corresponding parts throughout the several views of the drawings.

### DETAILED DESCRIPTION OF THE INVENTION

The invention utilizes a dog-bone shaped strap instead of a rectangular shaped strap. That is, an elongated strap has a first platform and a second platform linked by a connector that is substantially narrow than the first platform and the second platform. The first platform and the second platform are each configured to receive a stress sensitive device. For example, a circular MTJ is surrounded by a rounded strap (i.e., platform) that largely reduces the anisotropy of the structure to reduce stress. Advantageously, no changes in manufacturing are required to obtain such a dog-bone shaped strap. The strap may incorporate any number of platforms and connectors.

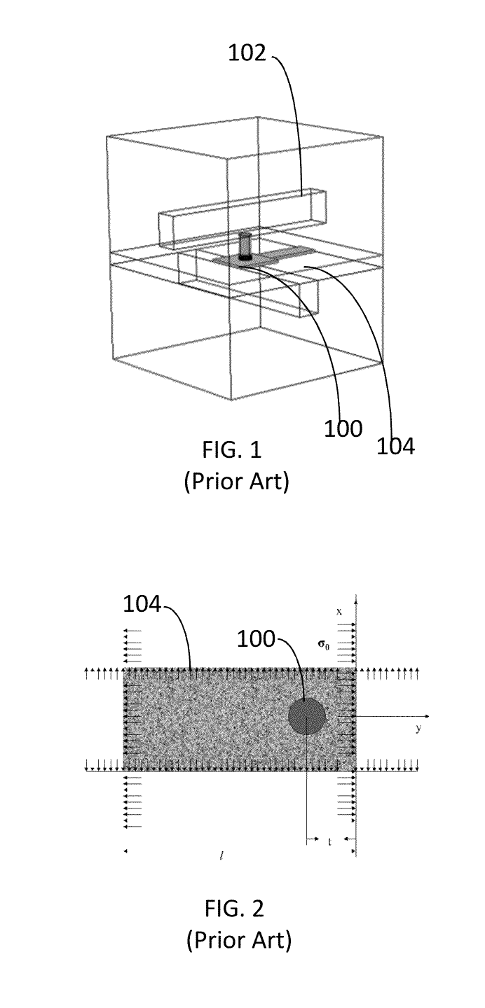

A generic way to connect a circular MTJ through multiple conductive layers is illustrated in FIG. 1. The magnetic stack 100 has a top surface connected to a conductive layer 102. A bottom surface of the stack 100 is connected to a strap 104.

FIG. 2 is a top view of a prior art rectangular strap 104 that surrounds the MTJ stack 100, and provides enough spatial margin in case of a miss-alignment of the MTJ during the manufacturing process. The rectangle needs to be long enough to connect the MTJ to a second structure or a different connection.

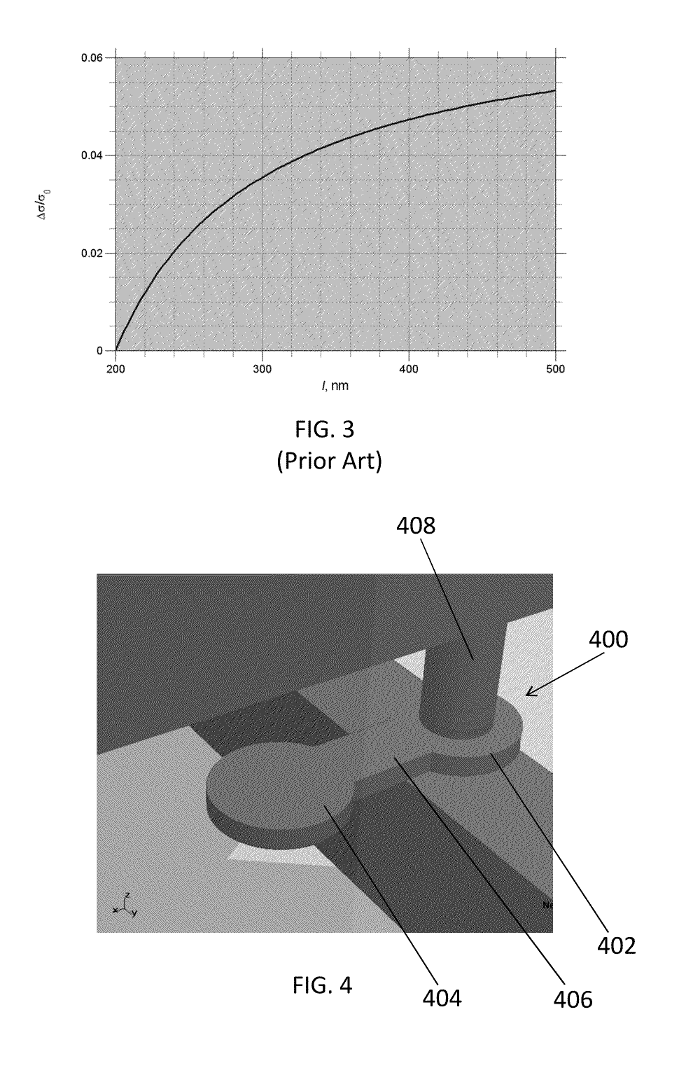

FIG. 3 illustrates the compressive stress (y-axis) calculated using comprehensive physical modeling as a function of the length (X-axis) of the rectangle in nm. In this calculation, the width of the rectangle has been chosen at an arbitrary 200 nm. When the length of the rectangle equals the width the stress is zero; thus, no anisotropy is created by the strap. The stress quickly increases when the length is larger than the width. The increase is more moderate when the length is large enough.

Such strong anisotropy creates through magnetostiction coupling a large effect on the magnetic device. The orientation of the magnetic domains could be pushed as much as 90° from the long axis of the rectangular strap. The negative effect on the performance of MTJs could include difficulty programming the device, reduced sensitivity, and in extreme cases inability to operate the device.

FIG. 4 illustrates a dog bone shaped strap 400 configured in accordance with an embodiment of the invention. The strap 400 includes a first platform 402 connected to a second platform 404 by a connector 406 that is substantially narrower than the first platform and the second platform. The first platform 402 and the second platform 404 are each configured to receive a stress sensitive device, such as an MTJ 408. In one embodiment, the connector is at least 25% narrower than the first platform and the second platform.

The shape of the strap is configured to create an isotropic area around an MTJ. That is, the platform area around an MTJ is substantially wider than the MTJ. For example, the platform is at least 25% wider than the MTJ.

In such a dog bone shape, a rounded area is placed under the circular MTJ, while the part of the strap connecting the junction to the next one is narrower. The manufacturing of such a structure is straightforward. The landing area is drawn as a simple square around the circular MTJ. Standard photolithography processes transform the square into a rounded area. Besides changing the size and shape of the mask, no additional changes are necessary to manufacture the structure.

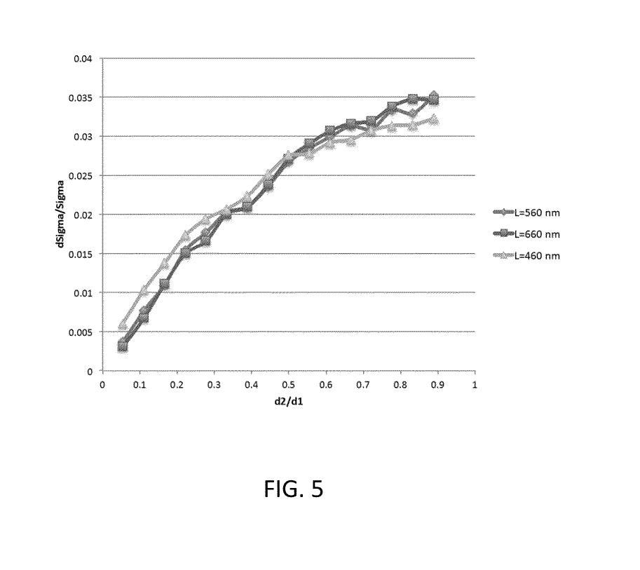

FIG. 5 illustrates the stress (Y-axis) resulting from such a modified strap, which is calculated using similar models as in FIG. 3. The parameter plotted on the X-axis is the ratio of d2 the volume of rectangular material connecting the MTJ, and dl the volume of isotropic material directly surrounding the MTJ. A very significant stress reduction occurs when the volume of the isotropic material increases in a relative term. Advantageously, with such a structure the length of the rectangular section does not play a significant role. On the other hand, it is not going to be practical to reduce the ratio below a certain level to keep the cell size small enough; there is a tradeoff. A ratio around 0.4 reduces the stress in half, which is very significant, while not significantly increasing the cell size.

Such a novel structure offers extremely significant stress reduction, while the implementation does not require any material changes in the manufacturing process. The approach also provides a well-rounded landing area for the MTJ in case of miss-alignments that could be created during the manufacturing process.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. An apparatus, comprising:
an elongated strap with a first platform and a second platform linked by a connector that is substantially narrower than the first platform and the second platform, wherein the first platform and the second platform are each configured to receive a stress sensitive device.

2. The apparatus of claim 1 wherein the connector is at least 25% narrower than the first platform and the second platform.

3. The apparatus of claim 1 wherein the first platform and the second platform are each configured to be substantially wider than the stress sensitive device.

4. The apparatus of claim 3 wherein the first platform and the second platform are each configured to be at least 25% wider than the stress sensitive device.

5. The apparatus of claim 1 wherein the first platform and the second platform are each configured to be substantially circular.

6. The apparatus of claim 1 wherein the stress sensitive device is a magnetic stack.

7. The apparatus of claim 1 wherein the stress sensitive device is a magnetic tunnel junction.
